(19) United States
(12) Patent Application Publication
(10) Pub. No.: US 2025/0076928 A1
(43) Pub. Date: Mar. 6, 2025

(54) DISPLAY DEVICE

(71) Applicant: Samsung Display Co., LTD., Yongin-si (KR)

(72) Inventor: SUNGSANG AHN, Yongin-si (KR)

(21) Appl. No.: 18/736,185

(22) Filed: Jun. 6, 2024

(30) Foreign Application Priority Data
Aug. 29, 2023 (KR) 10-2023-0113765

(51) Int. Cl. G06F 1/16

(52) U.S. Cl. CPC G06F 1/1652; G06F 1/1656; G06F 1/1681

(57) ABSTRACT

A display device includes a display module, a supporting plate disposed under the display module, and including a plate and a plurality of supporting bars arranged in a first direction along with the plate, and extending in a second direction crossing the first direction, a main case disposed under the supporting plate, a moving case which is disposed between the supporting plate and the main case, and which moves in the first direction with respect to the main case, and an elastic member disposed on an upper surface of the moving case, and coupled to the supporting plate. In a state in which the overlapping area of the moving case and the main case is at its minimum, the elastic member is stretched and applies elastic force to the supporting plate.

This application claims priority to Korean Patent Application No. 10-2023-0113765, filed on Aug. 29, 2023, and all the benefits accruing therefrom under 35 U.S.C. § 119, the content of which in its entirety is herein incorporated by reference.

### BACKGROUND

### 1. Field

The disclosure herein relates to a display device.

### 2. Description of the Related Art

An electronic apparatus that provides an image to a user, such as a smart phone, a digital camera, a laptop computer, a navigation system, and a smart television, includes a display device to display the image. The display device generates an image and provides the image to a user through a display screen.

Due to recent technological development of a display device, various types of display devices are being developed. For example, various display devices capable of extending or shrinking, or being deformed to a curved form are being developed. The display devices are easily portable, and may improve user convenience.

### SUMMARY

The disclosure provides a display device capable of preventing deformation of supporting bars that support a display module.

An embodiment of the inventive concept provides a display device including a display module, a supporting plate disposed under the display module, and including a plate and a plurality of supporting bars arranged in a first direction along with the plate, and extending in a second direction crossing the first direction, a main case disposed under the supporting plate, a moving case disposed between the supporting plate and the main case, and configured to move in the first direction with respect to the main case, and an elastic member disposed on an upper surface of the moving case, and coupled to the supporting plate. In a state in which an overlapping area of the moving case and the main case is at a minimum, the elastic member is stretched and applies elastic force to the supporting plate.

In an embodiment of the inventive concept, a display device includes a display module, a supporting plate which is disposed under the display module, and in which a plurality of guide grooves are defined, a main case disposed under the supporting plate, a moving case disposed between the main case and the supporting plate, and slidably coupled to the main case, and a plurality of elastic members disposed on an upper surface of the moving case, and coupled to the plurality of guide grooves. In a state in which the moving case moves in a first direction with respect to the main case, portions of the plurality of elastic members, which are coupled to the plurality of guide grooves, become close to each other or away from each other, and in a state in which a distance between the portions of the plurality of elastic members is at a maximum, the plurality of elastic members is stretched and applies elastic force to the supporting plate.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a perspective view of an embodiment of a display device according to the inventive concept;

FIG. 1B is a drawing illustrating an extended mode of the display device illustrated in FIG. 1A;

FIG. 2 is an exploded perspective view of the display device illustrated in FIG. 1A;

FIG. 3 is an exploded perspective view illustrating a module set illustrated in FIG. 2;

FIG. 4 is a cross-sectional view of a display module illustrated in FIG. 3;

FIG. 5 is a cross-sectional view of a display panel illustrated in FIG. 4;

FIG. 6 is a plan view of the display panel illustrated in FIG. 5;

FIG. 7 is a perspective view of a supporting plate illustrated in FIG. 3;

FIG. 8 is an exploded perspective view of an extension module illustrated in FIG. 2;

FIG. 9 is a drawing of an elastic member illustrated in FIG. 8;

FIG. 10 is a cross-sectional view of a pressing part illustrated in FIG. 8;

FIG. 11 is a drawing of a driving part and the pressing part illustrated in FIG. 8;

FIG. 12 is a drawing illustrating coupling of a driving part and a supporting plate;

FIGS. 13A to 13F are drawings illustrating an extended mode or a reduced mode of a display device;

FIGS. 14A and 14B are drawings illustrating supporting bars according to Comparative Example;

FIGS. 14C and 14D are drawings illustrating an embodiment of supporting bars according to the inventive concept; and

FIGS. 15A and 15B are drawings illustrating another embodiment of an elastic member according to the inventive concept.

### DETAILED DESCRIPTION

The advantages and features of the inventive concept and how to achieve them will become clear by referring to the embodiments described in detail below together with the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art, and the scope of the inventive concept as here is only defined by the claims. Like reference numbers or symbols refer to like elements throughout the specification.

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

Spatially relative terms, such as “beneath”, “below”, “lower”, “above”, “upper” and the like, may be used herein for ease of description to describe one element or feature's relationship to another element(s) or feature(s) as illustrated in the drawing figures. It will be understood that the spatially relative terms are intended to encompass different orientations of the device in use or operation in addition to the orientation depicted in the drawing figures. Like reference numbers or symbols refer to like elements throughout the specification.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Embodiments described in this specification are explained with reference to a plan view and a cross-sectional view, which are ideal schematic diagrams of the inventive concept. Therefore, the form of the illustration may be modified depending on manufacturing technology and/or tolerances. Therefore, the inventive concept is not limited to the specific form illustrated, but includes changes in form produced according to the manufacturing process. Therefore, the regions illustrated in the drawing have schematic properties, the shapes of the regions in the drawings are intended to illustrate specific shapes of an element, but not intended to limit the scope of the inventive concept.

Hereinafter, an embodiment of the inventive concept will be described in more detail with reference to the accompanying drawings.

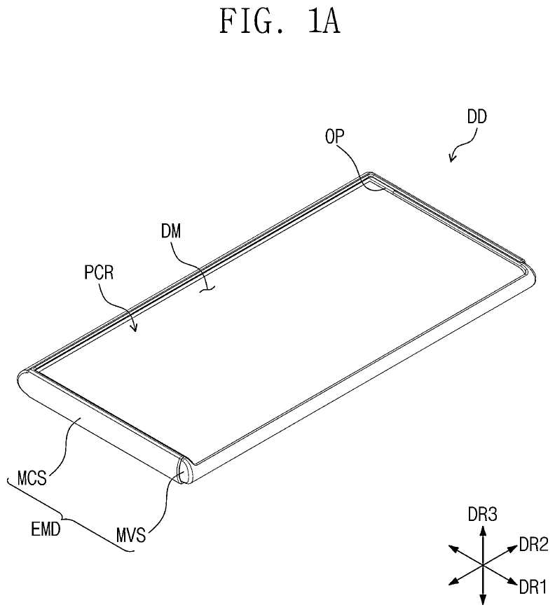

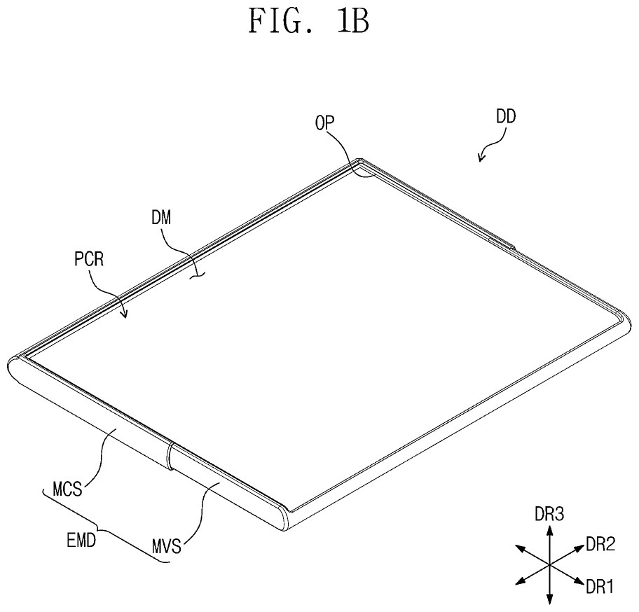

FIG. 1A is a perspective view of an embodiment of a display device according to the inventive concept. FIG. 1B is a drawing illustrating an extended mode of the display device illustrated in FIG. 1A.

Referring to FIG. 1A, a display device DD may include a module set PCR, and an extension module EMD which accommodates the module set PCR. The module set PCR may include a display module DM. The display module DM may be exposed to the outside through an opening OP defined in an upper part of the extension module EMD.

The extension module EMD may include a main case MCS and a moving case MVS. The moving case MVS may be coupled to the main case MCS to be moveable in a first direction DR1.

Hereinafter, a direction crossing the first direction DR1 is defined as a second direction DR2. A direction substantially perpendicular to a plane defined by the first and second directions DR1 and DR2 is defined as a third direction DR3. In this specification, “in a plan view” may refer to a state when viewed from the third direction DR3.

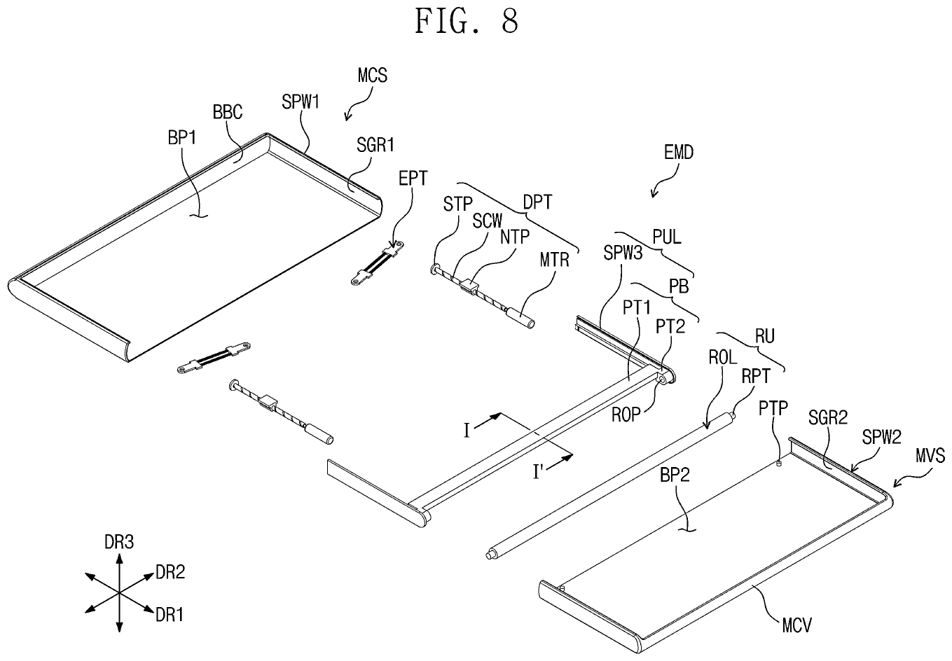

More particular compositions of the main case MCS and the moving case MVS will be described in detail with reference to an exploded perspective view of an extension module EMD illustrated in FIG. 8 below.

Referring to FIGS. 1A and 1B, the moving case MVS may move along the first direction DR1 to be away from, or to be close to the main case MCS. The overlapping area of the main case MCS and the moving case MVS may be changed.

When the moving case MVS moves in the first direction DR1, the area of the display module DM to be exposed may be controlled according to movement of the moving case MVS. According to the movement of the moving case MVS, a basic mode and an extended mode of the display device DD may be realized.

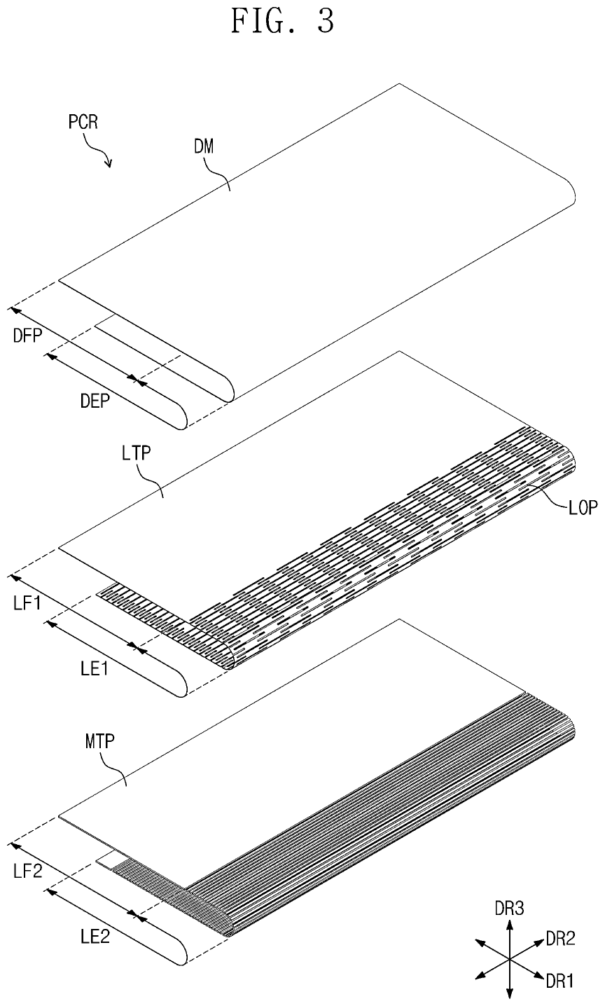

The display module DM may be a flexible display module, and supported by a supporting plate (as illustrated in FIG. 3 below) disposed under the display module DM. The display module DM and the supporting plate may be accommodated in the main case MCS and the moving case MVS. The display module DM and the supporting plate may be connected to the moving case MVS, and when the moving case MVS moves along the first direction DR1 from the main case MCS, the display module DM and the supporting plate may also move in the first direction DR1.

Although not illustrated in the drawing, a portion of the display module DM not exposed to the outside, other than a portion of the display module DM exposed through the opening OP, may be disposed in the moving case MVS.

Referring to FIG. 1B, the moving case MVS may move in the first direction DR1 to be away from the main case MCS. The display module DM, disposed on the supporting plate, moves together with the supporting plate in the first direction DR1 along the movement of the moving case MVS, and as a result, an exposed surface of the display module DM may be extended. As the exposed surface of the display module DM is extended, a user may view an image through a larger screen. A state of the display device DD where the exposed surface of the display module DM is extended may be defined as an extended mode.

Referring to FIG. 1A, the moving case MVS may move in the opposite direction of the first direction DR1 to be close to the main case MCS. When the moving case MVS moves toward the main case MCS at its maximum, the exposed surface of the display module DM may be set to a minimum. Such a state of the display device DD may be defined as a reduced mode.

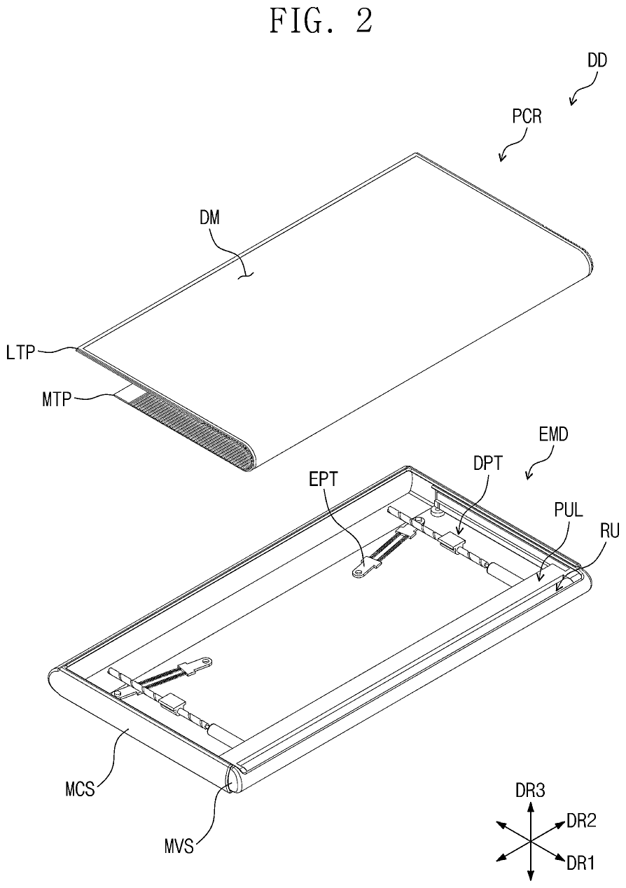

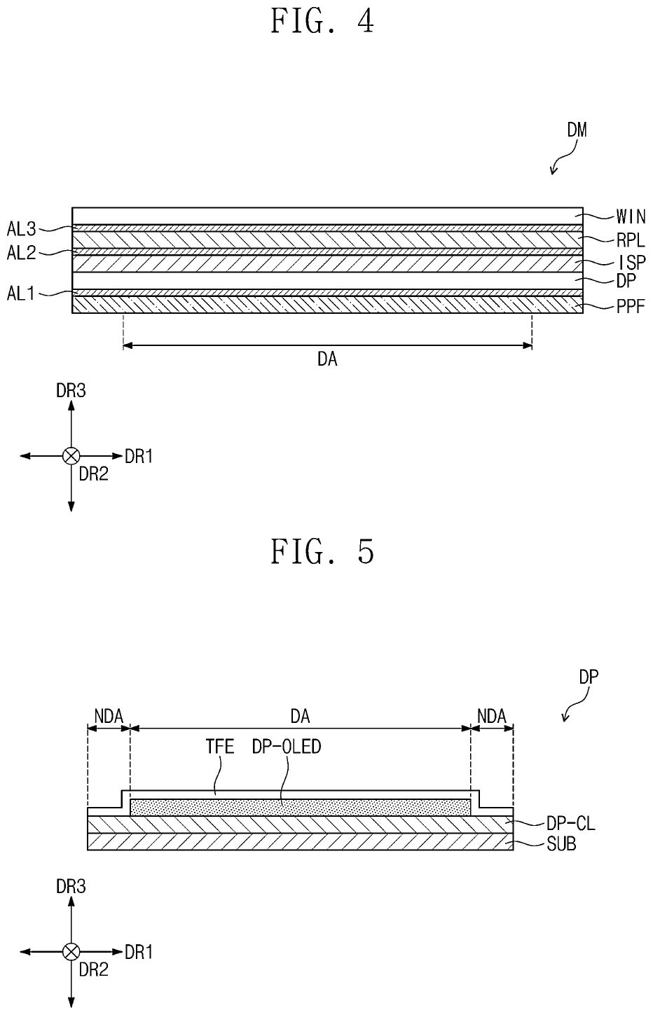

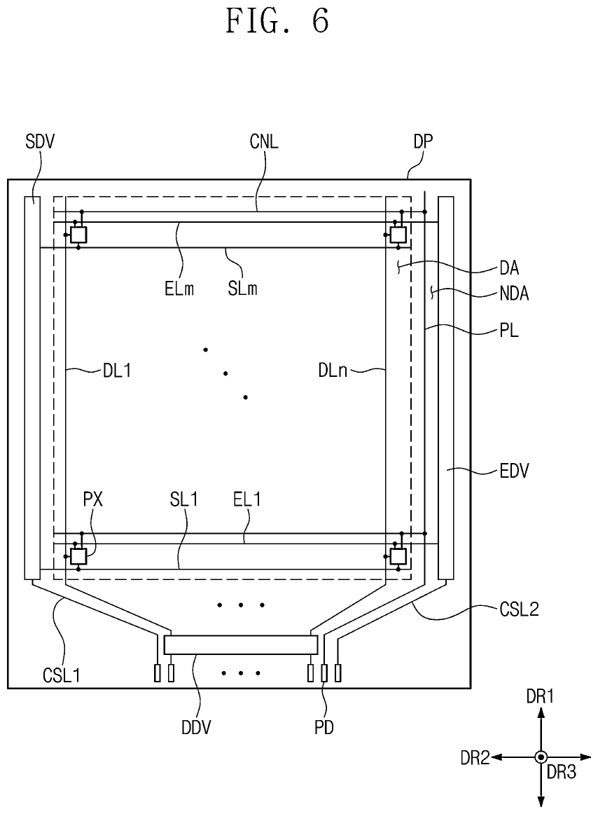

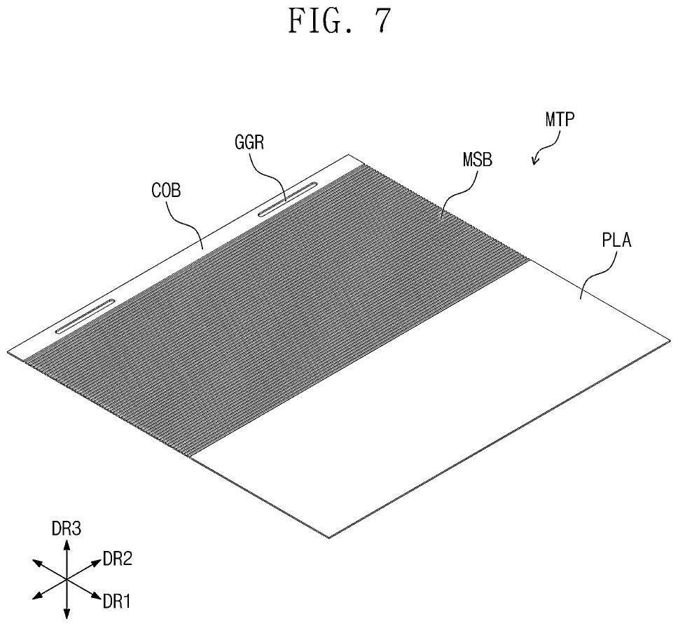

FIG. 2 is an exploded perspective view of the display device illustrated in FIG. 1A. FIG. 3 is an exploded perspective view of a module set illustrated in FIG. 2. FIG. 4 is a cross-sectional view of a display module illustrated in FIG. 3. FIG. 5 is a cross-sectional view of a display panel illustrated in FIG. 4. FIG. 6 is a plan view of the display panel illustrated in FIG. 5. FIG. 7 is a perspective view of a supporting plate illustrated in FIG. 3.

FIG. 2 illustrates a module set PCR and an extension module EMD in a reduced mode.

FIG. 7 illustrates a supporting plate MTP in an unfolded state.

Referring to FIGS. 2 and 3, the display device DD may include an extension module EMD and a module set PCR. The extension module EMD may include a main case MCS, a moving case MVS, a plurality of elastic members EPT, a roller part RU, a pressing part PUL, and a plurality of driving parts DPT. Particular compositions of the main case MCS, the moving case MVS, the plurality of elastic members EPT, the roller part RU, the pressing part PUL, and the plurality of driving parts DPT will be described in detail with reference to FIGS. 8 to 12 later.

As the moving case MVS moves in a first direction DR1 with respect to the main case MCS, the extension module EMD may extend or shrink in the first direction DR1.

The extension module EMD may accommodate the module set PCR. A portion of the module set PCR may be accommodated in the moving case MVS, and may thus move in the first direction DR1 with respect to the main case MCS. The area of an exposed surface of the module set PCR may be controlled according to movement of the moving case MVS. In a reduced mode, the module set PCR may be accommodated in the moving case MVS. In an extended mode, the module set PCR may extend out of the moving case MVS.

The module set PCR may include a display module DM, an upper plate LTP, and a supporting plate MTP. When the display module DM is unfolded, the display module DM may have a quadrangular shape, e.g., rectangular shape including long sides extending in the first direction DR1 and short sides extending in a second direction DR2.

Referring to FIG. 3, the display module DM may operate in the reduced mode where the display module DM shrinks into the moving case MVS (refer to FIG. 2) or in the extended mode where the display module DM extends out of the moving case MVS. The display module DM may include a fixed region DFP and an extending region DEP. When the display device DD (refer to FIG. 1) is in the reduced mode, a portion of the display module DM exposed flat to the outside may be defined as the fixed region DFP, and a portion of the display module DM not exposed flat to the outside may be defined as the extending region DEP.

When the display device DD (refer to FIG. 1) is in the extended mode, a portion of the extending region DEP may be exposed flat to the outside. The extending region DEP may extend from the fixed region DFP in a first direction DR1. The extending region DEP and the fixed region DFP may be disposed in the first direction DR1.

Referring to FIG. 4, the display module DM may include a display panel DP, an input-sensing part ISP, an anti-reflection layer RPL, a window WIN, a panel protection film PPF, and first to third adhesive layers AL1 to AL3.

The display panel DP may be a flexible display panel. The display panel DP in an embodiment of the inventive concept may be an emission-type display panel, but is not particularly limited thereto. In an embodiment, the display panel DP may be an organic light-emitting display panel or an inorganic light-emitting display panel, for example. A light-emitting layer of the organic light-emitting display panel may include an organic light-emitting material. A light-emitting layer of the inorganic light-emitting display panel may include quantum dots, quantum rods, or the like. Hereinafter, the display panel DP is described as the organic light-emitting display panel.

The input-sensing part ISP may be disposed on the display panel DP. The input-sensing part ISP may include a plurality of sensing portions (not shown) for detecting external inputs in a capacitance manner. The input-sensing part ISP may be directly manufactured on the display panel DP in manufacturing the display device DD. However, the inventive concept is not limited thereto, and the input-sensing part ISP may be manufactured separately from the display panel DP, and bonded to the display panel DP through an adhesive layer.

The anti-reflection layer RPL may be disposed on the input-sensing part ISP. The anti-reflection layer RPL may be defined as an external light anti-reflection film. The anti-reflection layer RPL may reduce the reflectance for external light incident from above the display device DD toward the display panel DP. When the external light directed toward the display panel DP is

reflected on the display panel DP to be provided back to a user in the outside, the user may view the external light like in a mirror. To prevent this phenomenon, the anti-reflection layer RPL may include a plurality of color filters that display the same colors as pixels of the display panel DP, for example.

The color filters may filter external light into the same colors as the pixels. In this case, the external light may not be viewed from the user. However, the inventive concept is not limited thereto, and the anti-reflection layer RPL may include a retarder and/or polarizer in order to reduce the reflectance for external light.

The window WIN may be disposed on the anti-reflection layer RPL. The window WIN may protect the display panel DP, the input-sensing part ISP, and the anti-reflection layer RPL from external scratches and impact.

The panel protection film PPF may be disposed under the display panel DP. The panel protection film PPF may protect a lower part of the display panel DP. The panel protection film PPF may include a flexible plastic material such as polyethylene terephthalate (“PET”).

The first adhesive layer AL1 may be disposed between the display panel DP and the panel protection film PPF, and the display panel DP and the panel protection film PPF may be bonded to each other by the first adhesive layer AL1. The second adhesive layer AL2 may be disposed between the anti-reflection layer RPL and the input-sensing part ISP, and the anti-reflection layer RPL and the input-sensing part ISP may be bonded to each other by the second adhesive layer AL2. The third adhesive layer AL3 may be disposed between the window WIN and the anti-reflection layer RPL, and the window WIN and the anti-reflection layer RPL may be bonded to each other by the third adhesive layer AL3.

Referring to FIG. 5, the display panel DP may include a substrate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

The substrate SUB may include a display region DA and a non-display region NDA around the display region DA. The substrate SUB may include a flexible plastic material such as polyimide (“PI”). The display element layer DP-OLED may be disposed on the display region DA.

A plurality of pixels may be disposed on the circuit element layer DP-CL and the display element layer DP-OLED. The pixels may each include transistors disposed on the circuit element layer DP-CL and a light-emitting element disposed on the display element layer DP-OLED to be connected to the transistors. The configuration of the pixel will be described in detail later.

The thin-film encapsulation layer TFE may be disposed on the circuit element layer DP-CL to cover the display element layer DP-OLED. The thin-film encapsulation layer TFE may protect the pixels from moisture, oxygen, and foreign substances.

Referring to FIG. 6, the display panel DP may include a scan driver SDV, a data driver DDV, a light emission driver EDV, and a plurality of pads PD.

The display panel DP may have a quadrangular shape, e.g., rectangular shape including short sides extending in a first direction DR1 and long sides extending in a second direction DR2, but the shape of the display panel DP is not limited thereto. The display panel DP may include a display region DA and a non-display region NDA surrounding the display region DA.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, first and second power lines PL1 and PL2, and connection lines CNL. Here, m and n are natural numbers.

The pixels PX may be disposed in the display region DA. The scan driver SDV and the light emission driver EDV may be respectively disposed in the non-display region NDA adjacent to the long sides of the display panel DP. The data driver DDV may be disposed in the non-display region NDA adjacent to any one short side among the short sides of the display panel DP. In a plan view, the data driver DDV may be adjacent to a lower end of the display panel DP.

The scan lines SL1 to SLm may extend in the second direction DR2 to be connected to the pixels PX and the scan driver SDV. The data lines DL1 to DLn may extend in the first direction DR1 to be connected to the pixels PX and the data driver DDV. The emission lines EL1 to ELm may extend in the second direction DR2 to be connected to the pixels PX and the light emission driver EDV.

The power line PL may extend in the first direction DR1 to be disposed in the non-display region NDA. The power line PL may be disposed between the display region DA and the light emission driver EDV, but the inventive concept is not limited thereto, and the power line PL may also be disposed between the display region DA and the scan driver SDV.

The connection lines CNL may extend in the second direction DR2 and be disposed in the first direction DR1, and may thus be connected to the power line PL and the pixels PX. A driving voltage may be applied to the pixels PX through the connection lines CNL and the power line PL which are connected to each other.

The first control line CSL1 may be connected to the scan driver SDV, and extend toward the lower end of the display panel DP. The second control line CSL2 may be connected to the light emission driver EDV, and extend toward the lower end of the display panel DP. The data driver DDV may be disposed between the first control line CSL1 and the second control line CSL2.

The data lines DL1 to DLn may be connected to corresponding pads PD through the data driver DDV. In an embodiment, the data lines DL1 to DLn may be connected to the data driver DDV, and the data driver DDV may be connected to the pads PD corresponding to the data lines DL1 to DLn, for example.

Although not illustrated in the drawing, a printed circuit board may be connected to the pads PD, and a timing controller and a voltage generator may be disposed on the printed circuit board. The timing controller may be manufactured as an integrated circuit chip to be disposed (e.g., mounted) on the printed circuit board. The timing controller and the voltage generator may be connected to the pads PD through the printed circuit board.

A scan control signal may be provided to the scan driver SDV through the first control line CSL1. An emission control signal may be provided to the light emission driver EDV through the second control line CSL2. A data control signal may be provided to the data driver DDV. The timing controller may receive image signals from the outside, and convert data formats of the image signals into those in accordance with interface specification of the data driver DDV, and may thus provide the converted data to the data driver DDV.

The scan driver SDV may generate a plurality of scan signals in response to the scan control signal. The scan signals may be applied to the pixels PX through the scan lines SL1 to SLm. The scan signals may be applied to the pixels PX in sequence.

The data driver DDV may generate a plurality of data voltages, corresponding to the image signals, in response to the data control signal. The data voltages may be applied to the pixels PX through the data lines DL1 to DLn. The light emission driver EDV may generate a plurality of emission signals in response to the emission control signal. The emission signals may be applied to the pixels PX through the emission lines EL1 to ELm.

The pixels PX may receive the data voltages in response to the scan signals. In response to the emission signals, the pixels PX may emit light of brightness corresponding to the data voltages to thereby display an image. The emission time of the pixels PX may be controlled by the emission signals.

Referring to FIG. 3, the upper plate LTP may be disposed under the display module DM. An upper surface of the upper plate LTP may be attached to a lower surface of the display module DM.

When the upper plate LTP is unfolded, the upper plate LTP may have a quadrangular shape, e.g., rectangular shape including long sides extending in the first direction DR1 and short sides extending in the second direction DR2.

The upper plate LTP may include a metal material such as stainless steel (e.g., SUS316), but the metal material of the upper plate LTP is not limited thereto. In addition, the inventive concept is not limited thereto, and the upper plate LTP may include a nonmetal material such as plastic.

The upper plate LTP may include a first fixed portion LF1 and a first extending portion LE1. The first fixed portion LF1 may overlap the fixed region DFP of the display module DM. The first extending portion LE1 may overlap the extending region DEP of the display module DM. The first extending portion LE1 may extend from the first fixed portion LF1 in the first direction DR1. The first extending portion LE1 and the first fixed portion LF1 may be arranged in the first direction DR1.

A plurality of openings LOP may be defined in the first extending portion LE1. The openings LOP may overlap the extending region DEP of the display module DM. Since the openings LOP are defined, the first extending portion LE1 may decrease in rigidity. Therefore, when the openings LOP are defined in the upper plate LTP, flexibility of the upper plate LTP may increase more than it does when the openings LOP are not defined. As a result, the upper plate LTP may be bendable more easily.

Referring to FIGS. 3 and 7, the supporting plate MTP may be disposed under the upper plate LTP and the display module DM. An upper surface of the supporting plate MTP may be attached to a lower surface of the upper plate LTP. The supporting plate MTP may be coupled to the upper plate LTP through welding, but the inventive concept is not limited thereto, and the supporting plate MTP may be coupled to the upper plate LTP in various ways.

The supporting plate MTP may include a metal material such as stainless steel (e.g., SUS316), but the metal material of the supporting plate MTP is not limited thereto. In addition, the inventive concept is not limited thereto, and the supporting plate MTP may include a nonmetal material such as plastic.

The supporting plate MTP may include a second fixed portion LF2 and a second extending portion LE2. The second fixed portion LF2 may overlap the first fixed portion LF1 and the fixed region DFP. The second extending portion LE2 may overlap the first extending portion LE1 and the extending region DEP.

When the display device DD (refer to FIG. 1) is in the reduced mode or the extended mode, the second fixed portion LF2 may not be accommodated in the moving case MVS, and may be exposed to the outside of the moving case MVS.

When unfolded, the second fixed portion LF2 may include a plate PLA having a quadrangular shape, rectangular shape including long sides extending in a first direction DR1 and short sides extending in a second direction DR2.

The second extending portion LE2 may include a plurality of supporting bars MSB. The supporting bars MSB may extend in the second direction DR2 to be disposed in the first direction DR1. The supporting bars MSB and the plate PLA may be disposed in the first direction DR1. The openings LOP of the upper plate LTP, illustrated in FIG. 3, may each overlap a portion between two supporting bars MSB adjacent to each other.

A supporting bar MSB spaced farthest apart from the plate PLA, among the plurality of supporting bars MSB, may be defined as a coupling supporting bar COB. Guide grooves GGR may be defined in an upper surface of the coupling supporting bar COB. The guide grooves GGR may be defined to be spaced apart from each other in the second direction DR2. The guide grooves GGR may each extend in the second direction DR2.

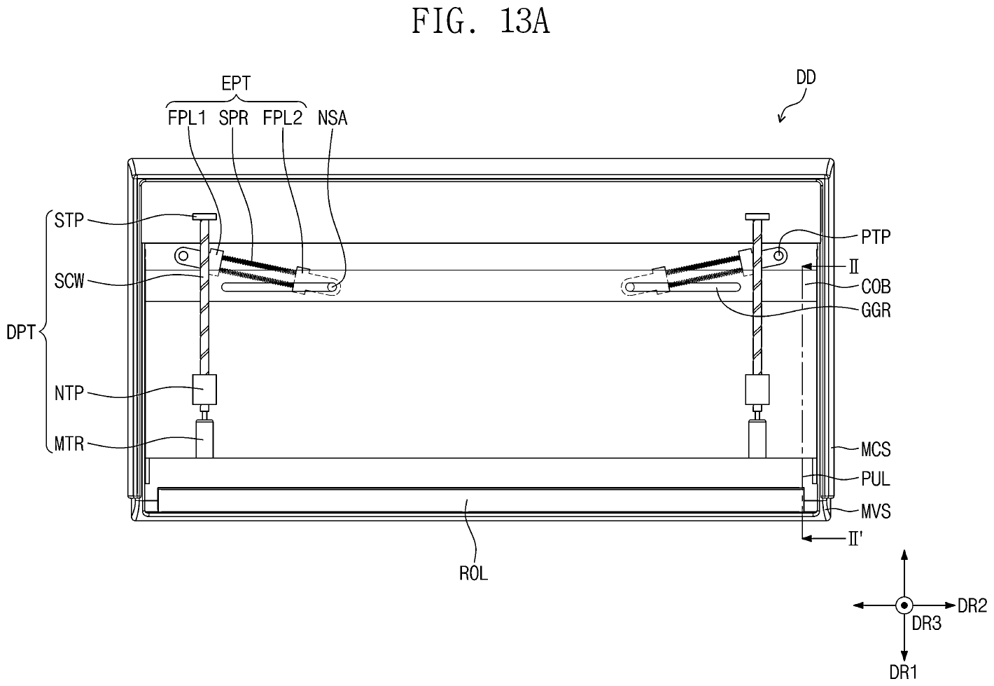

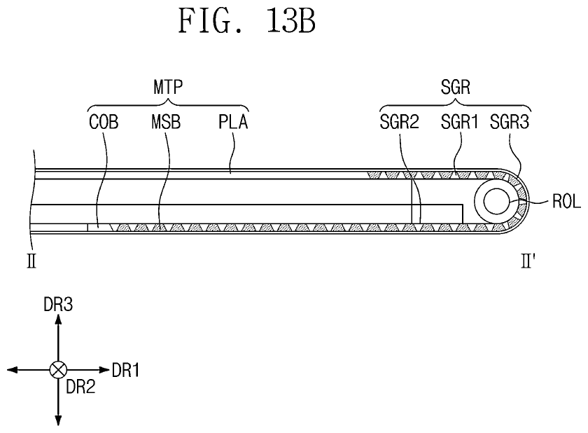

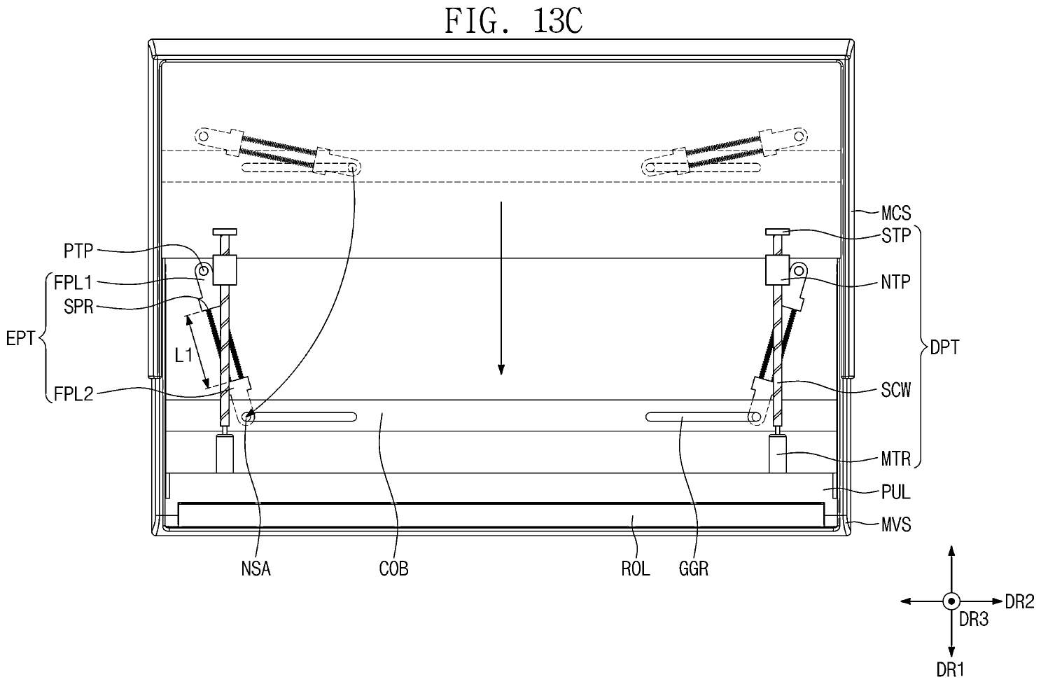

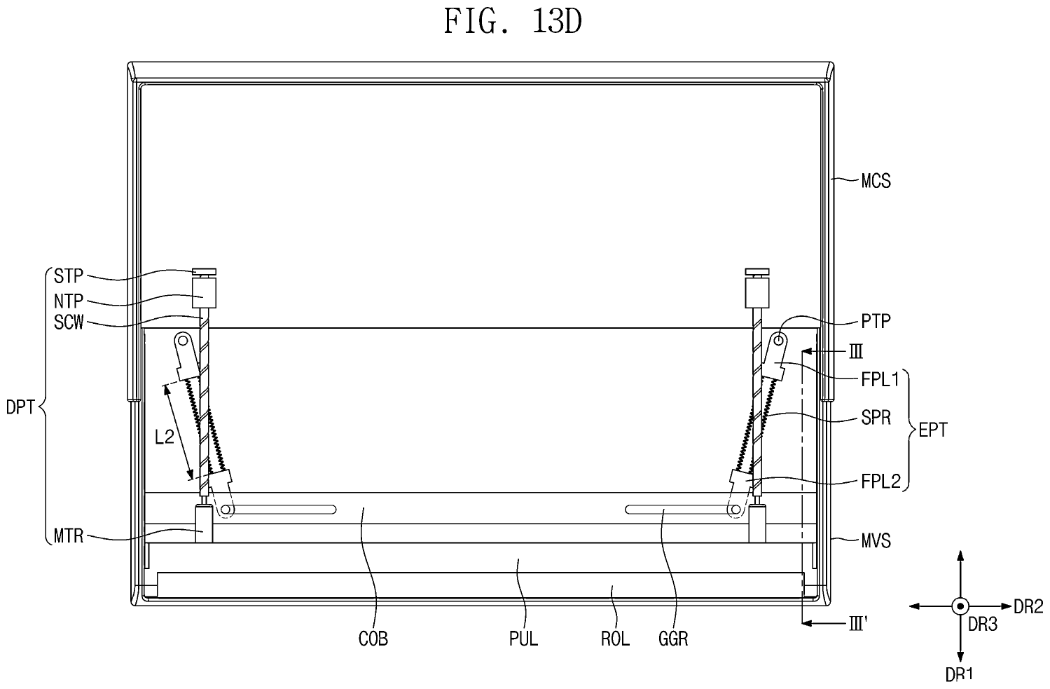

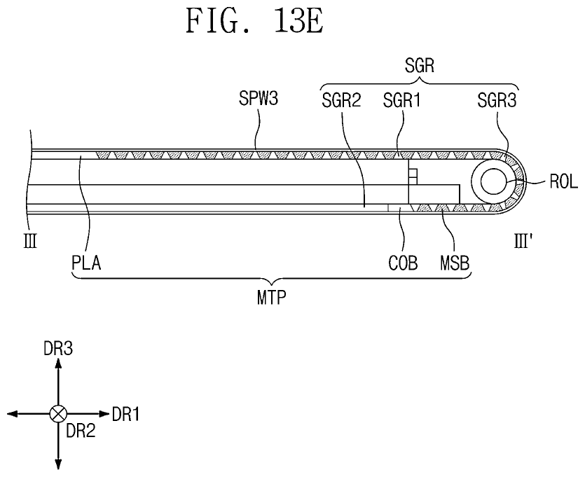

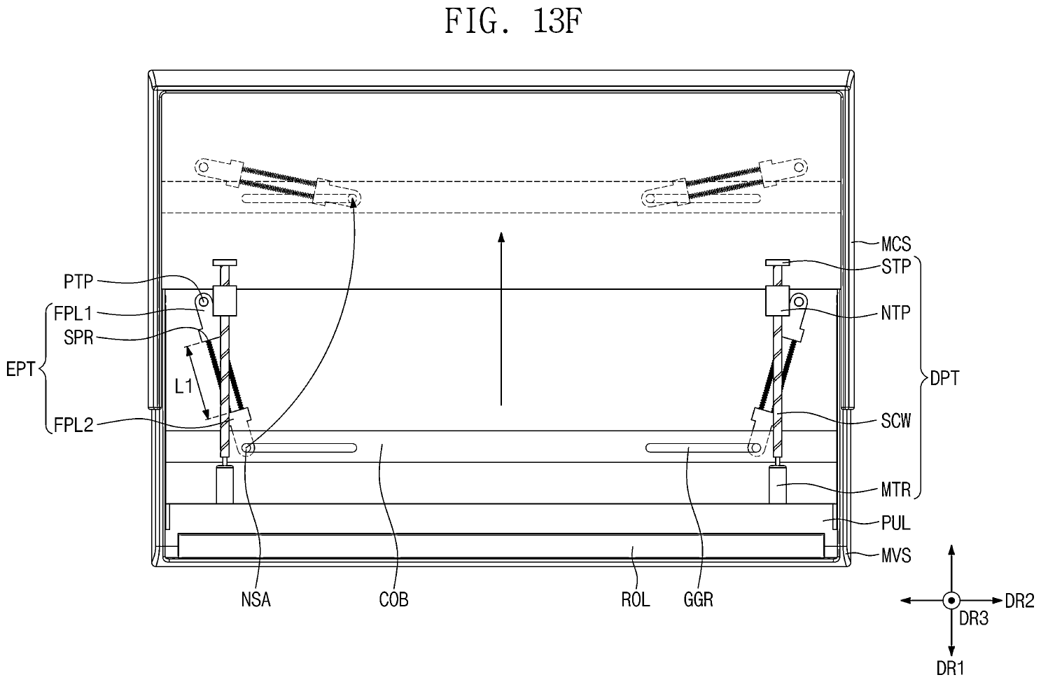

The coupling supporting bar COB may be coupled to the elastic members EPT (refer to FIG. 2). The elastic members EPT (refer to FIG. 2) may each be coupled to a corresponding guide groove GGR among the guide grooves GGR. The coupling of the elastic members EPT (refer to FIG. 2) and the coupling supporting bar COB will be described in detail with reference to FIG. 13A.

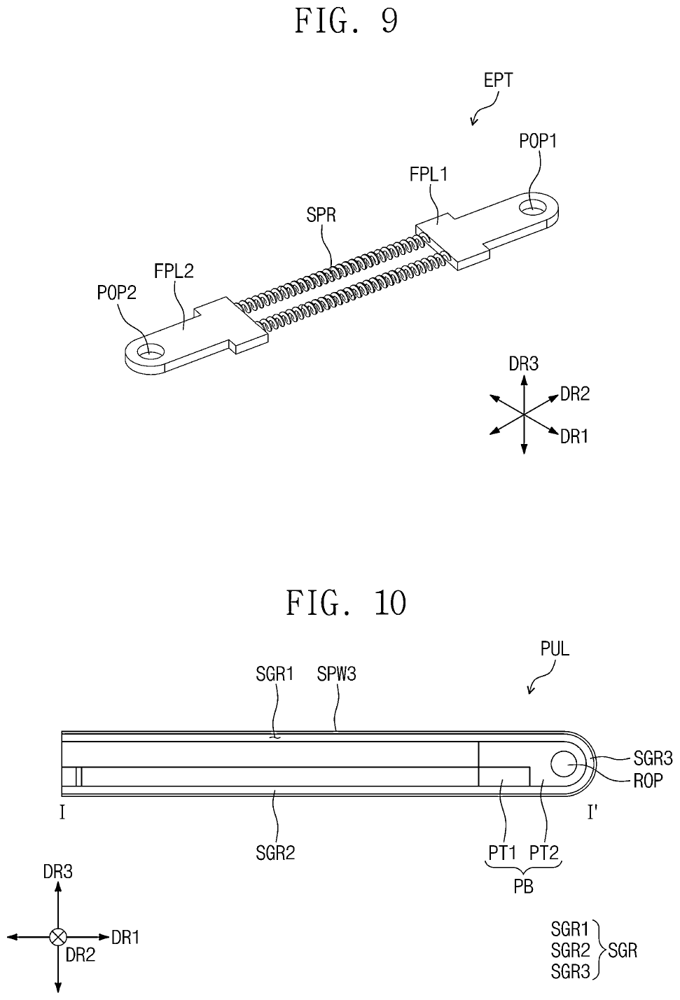

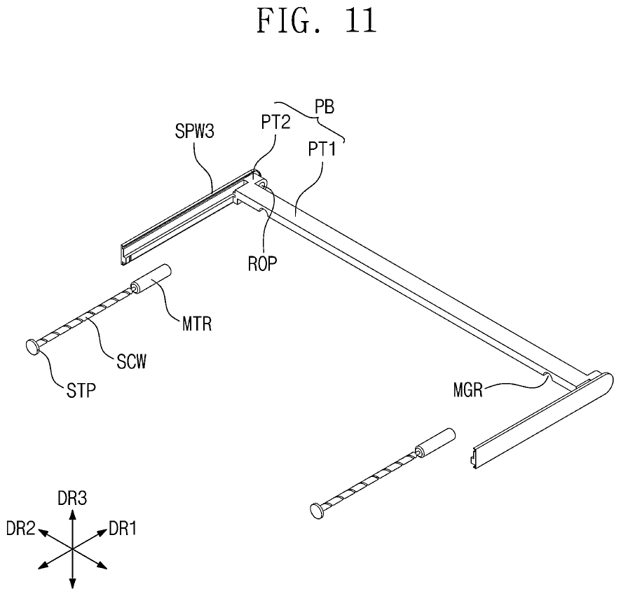

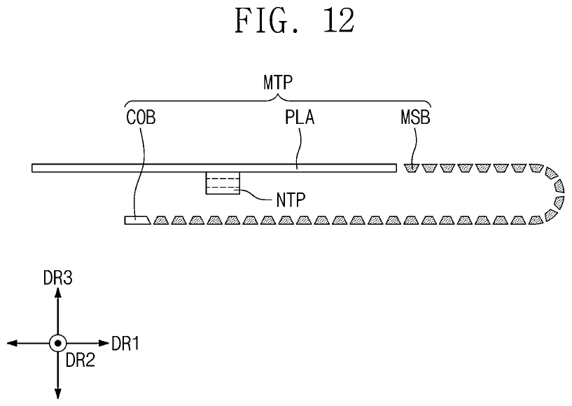

FIG. 8 is an exploded perspective view of the extension module illustrated in FIG. 2. FIG. 9 is a drawing of an elastic member illustrated in FIG. 8. FIG. 10 is a cross-sectional view of a pressing part illustrated in FIG. 8. FIG. 11 is a drawing of a driving part and the pressing part illustrated in FIG. 8. FIG. 12 is a drawing illustrating coupling of a driving part and a supporting plate.

FIG. 10 is an exemplary cross-sectional view taken along line I-I′ of FIG. 8.

FIG. 11 is a perspective view illustrating a driving part when viewed from another direction.

In FIG. 11, nut portions NTP are omitted, for example.

In FIG. 12, only the nut portion NTP, of the driving part DPT, is illustrated.

Referring to FIG. 8, the extension module EMD may include a main case MCS, a moving case MVS, elastic members EPT, driving parts DPT, a pressing part PUL, and a roller part RU. The main case MCS may include a first bottom portion BP1, a fixation cover BBC, and first sidewall portions SPW1. The first bottom portion BP1 may have a shape of a flat plate defined by a first direction DR1 and a second direction DR2. The first bottom portion BP1 may have a quadrangular shape, e.g., rectangular shape including short sides extending in the first direction DR1 and long sides extending in the second direction DR2.

The fixation cover BBC may be disposed adjacent to one side portion among opposite side portions of the first bottom portion BP1 that are opposed to each other in the first direction DR1. The fixation cover BBC may extend from the first side portion of the first bottom portion BP1 in a third direction DR3. The fixation cover BBC may extend in the second direction DR2 along a long side of the first bottom portion BP1. The first side portion, among opposite side portions of the first bottom portion BP1 opposed to each other in the first direction DR1, may be defined as a side opposed to an opposite side facing the moving case MVS.

The first sidewall portions SPW1 may be respectively disposed adjacent to opposite sides of the first bottom portion BP1 that are opposed to each other in the second direction DR2. The first sidewall portions SPW1 may face each other in the second direction DR2. The first sidewall portions SPW1 may extend in the first direction DR1 along the short sides of the first bottom portion BP1, respectively. Respective first side portions, among opposite side portions opposed to each other in the first direction DR1, of the first sidewall portions SPW1, may be connected to the fixation cover BBC. The first side portion, among opposite side portions opposed to each other in the first direction DR1, of each of the first sidewall portions SPW1, may be defined as a side opposed to an opposite side facing the moving case MVS.

First sliding grooves SGR1 may be respectively defined in mutually facing surfaces of the first sidewall portions SPW1. The first sliding grooves SGR1 may extend in the first direction DR1. The first sliding grooves SGR1 may extend from second side portions to the first side portions of the first sidewall portions SPW1, respectively.

The moving case MVS may include a second bottom portion BP2, second sidewall portions SPW2, coupling protruding portions PTP, and a moving cover MCV. The second bottom portion BP2 may have a shape of a flat plate defined by the first direction DR1 and the second direction DR2. The second bottom portion BP2 may have short sides extending in the first direction DR1 and long sides extending in the second direction DR2.

The moving cover MCV may be disposed adjacent to one side portion among opposite side portions of the second bottom portion BP2 that are opposed to each other in the first direction DR1. The moving cover MCV may extend from the first side portion of the second bottom portion BP2 in the third direction DR3. The moving cover MCV may extend in the second direction DR2 along a long side of the second bottom portion BP2. The first side portion, among the opposite side portions of the second bottom portion BP2 that are opposed to each other in the first direction DR1, may be defined as a side opposed to an opposite side facing the main case MCS.

The second sidewall portions SPW2 may be respectively disposed adjacent to opposite side portions of the second bottom portion BP2 opposed to each other in the second direction DR2. The second sidewall portions SPW2 may face each other in the second direction DR2. The second sidewall portions SPW2 may extend in the first direction DR1 along the short sides of the second bottom portion BP2, respectively. First side portions, among opposite side portions opposed to each other in the first direction DR1, of the second sidewall portions SPW2 may be respectively connected to opposite side portions of the moving cover MCV opposed to each other in the second direction DR2. The first side portion, among the opposite side portions opposed to each other in the first direction DR1, of each of the second sidewall portions SPW2, may be defined as a side opposed to an opposite side facing the main case MCS.

Second sliding grooves SGR2 may be respectively defined in mutually facing surfaces of the second sidewall portions SPW2. The second sliding grooves SGR2 may extend in the first direction DR1. The second sliding grooves SGR2 may extend from second side portions to the first side portions of the second sidewall portions SPW2.

The coupling protruding portions PTP may be disposed on an upper surface of the second bottom portion BP2. The coupling protruding portions PTP may be spaced apart from each other in the second direction DR2 to be disposed on the upper surface of the second bottom portion BP2. The coupling protruding portions PTP may be disposed adjacent to second side portion, among the opposite side portions of the second bottom portion BP2 opposed to each other in the first direction DR1. In a plan view, the coupling protruding portions PTP may be disposed between the second sidewall portions SPW2. In an embodiment, the coupling protruding portions PTP may each have a cylindrical shape, for example.

The moving case MVS may be disposed on the main case MCS. The second bottom portion BP2 may be disposed on the first bottom portion BP1. The second sidewall portions SPW2 may be disposed on the first sliding grooves SGR1 defined in the first sidewall portions SPW1. The second sidewall portions SPW2 may be coupled to the first sidewall portions SPW1 to be slidable in the first direction DR1. The second sidewall portions SPW2 may move back and forth in the first direction DR1 with respect to the first sidewall portions SPW1.

Referring to FIGS. 2, 8, and 9, the elastic members EPT may be disposed on the upper surface of the second bottom portion BP2. First side portions of the elastic members EPT may be coupled to the coupling protruding portions PTP, respectively. Although not illustrated in the drawing, second side portions of the elastic members EPT, disposed to be opposed to the first side portions, may be coupled to the coupling supporting bar COB (refer to FIG. 7). The coupling of the elastic members EPT and the coupling supporting bar COB will be described in detail with reference to FIG. 13A.

FIGS. 2 and 8 illustrate two elastic members EPT, but the number of the elastic members EPT is not limited thereto. Hereinafter, for the convenience of description, any one elastic member EPT among the elastic members EPT will be described.

The elastic member EPT may include a first fixation portion FPL1, a second fixation portion FPL2, and an elastic body SPR. The elastic body SPR may be disposed between the first fixation portion FPL1 and the second fixation portion FPL2. The first fixation portion FPL1 and the second fixation portion FPL2 may be connected to each other by the elastic body SPR.

When the elastic member EPT is disposed on the upper surface of the second bottom portion BP2, the coupling protruding portion PTP may be coupled to the elastic member EPT. A first coupling opening POPI may be defined in the first fixation portion FPL1. The first coupling opening POPI may correspond to the shape of the coupling protruding portion PTP. The coupling protruding portion PTP may be disposed in the first coupling opening POP1.

The coupling of the elastic member EPT may be made such that the elastic member EPT rotates about a rotation axis parallel to the third direction DR3. Since the coupling protruding portion PTP has a cylindrical shape, the elastic member EPT may be rotatable about the rotation axis parallel to the third direction DR3.

A second coupling opening POP2 may be defined in the second fixation portion FPL2. The second fixation portion FPL2 may be coupled to the coupling supporting bar COB (refer to FIG. 7) through the guide groove GGR (refer to FIG. 7) of the coupling supporting bar COB (refer to FIG. 7) and a coupling unit NSA (refer to FIG. 13A) passing through the second coupling opening POP2. The coupling of the second fixation portion FPL2 and the coupling supporting bar COB (refer to FIG. 7) will be described in detail with reference to FIG. 13A.

The elastic body SPR may be connected to the moving case MVS through the first fixation portion FPL1. The elastic body SPR may be connected to the coupling supporting bar COB (refer to FIG. 7) through the second fixation portion FPL2. The elastic body SPR may be connected to the supporting plate MTP (refer to FIG. 3) through the second fixation portion FPL2. The elastic body SPR may be connected to the module set PCR (refer to FIG. 3) through the second fixation portion FPL2.

In an embodiment, the elastic body SPR may include a tension spring, for example. The tension spring may be defined as a spring which tends to return to an initial length when it becomes longer than the initial length. The elastic body SPR may apply elastic force to the supporting plate MTP (refer to FIG. 7). This will be described in detail with reference to FIG. 13D.

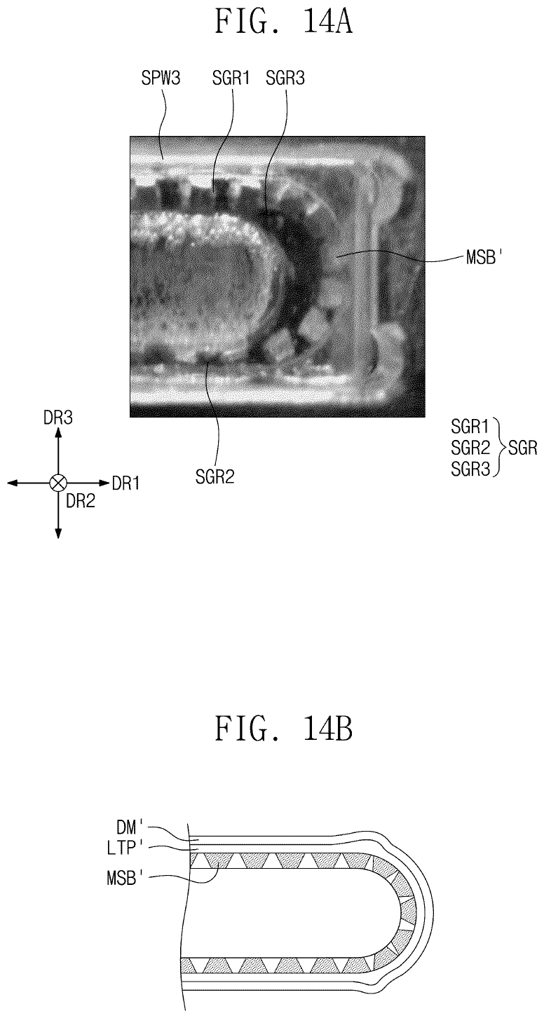

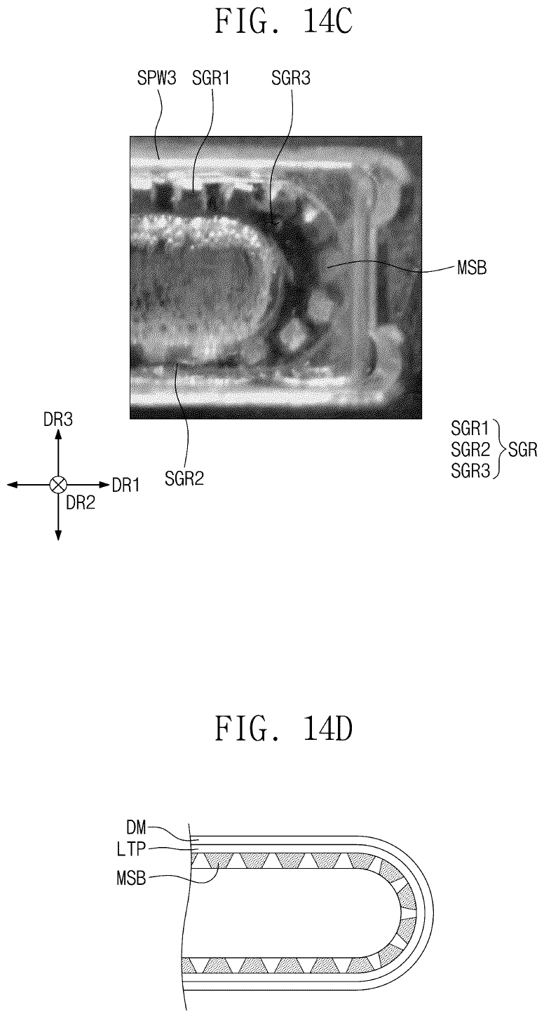

It is illustrated that the elastic body SPR is connected to the moving case MVS through the first fixation portion FPL1, and is connected to the supporting plate MTP (refer to FIG. 7) through the second fixation portion FPL2, but the inventive concept is not limited thereto, and the first fixation portion FPL1 and the second fixation portion FPL2 may be omitted. This will be described in detail with reference to FIGS. 14A and 14B.

Referring to FIGS. 2, 8, 9, and 11, the pressing part PUL may be coupled to the moving case MVS. The pressing part PUL may be coupled to the second sidewall portions SPW2. The pressing part PUL may be disposed on the second sliding grooves SGR2 defined in the second sidewall portions SPW2.

The pressing part PUL may include a stick portion PB and third sidewall portions SPW3. The stick portion PB may extend in a second direction DR2. The stick portion PB may include a first portion PT1 and second portions PT2. The first portion PT1 may extend in the second direction DR2. The second portions PT2 may be respectively disposed on opposite sides of the first portion PT1 that are opposed to each other in the second direction DR2. The second portions PT2 may face each other in the second direction DR2. The second portions PT2 may extend in a first direction DR1 respectively from the opposite sides of the first portion PT1 opposed to each other in the second direction DR2. Substantially, the first portion PT1 and the second portions PT2 may be unitary.

Driving grooves MGR, illustrated in FIG. 11, may be defined in the first portion PT1. The driving grooves MGR may be defined in one side portion among opposite side portions of the first portion PT1 that are opposed to each other in the first direction DR1. The first side portion, among the opposite side portions of the first portion PT1 opposed to each other in the first direction DR1, may be defined as a side facing the main case MCS.

The driving grooves MGR may be spaced apart from each other in the second direction DR2. The driving grooves MGR may each have a partially circular shape. When viewed from the first direction DR1, the driving grooves MGR may extend from a lower surface of the first portion PT1 in a third direction DR3, and may each have a concave shape.

Roller openings ROP may be defined in the second portions PT2. The roller openings ROP may be respectively defined in surfaces of the second portions PT2 facing each other in the second direction DR2. When viewed from the second direction DR2, the roller openings ROP may each have a circular shape.

Referring to FIGS. 2, 8, and 10, the third sidewall portions SPW3 may be respectively disposed on opposite side portions of the stick portion PB that are opposed to each other in the second direction DR2. The third sidewall portions SPW3 may be respectively coupled to the second portions PT2 of the stick portion PB. The third sidewall portions SPW3 may be respectively coupled onto surfaces that are opposed to the mutually facing surfaces of the second portions PT2. The third sidewall portions SPW3 may face each other in the second direction DR2.

The third sidewall portions SPW3 may be coupled to the second sidewall portions SPW2. The third sidewall portions SPW3 may be disposed on the second sliding grooves SGR2 defined in the second sidewall portions SPW2, respectively. The third sidewall portions SPW3 may have a shape corresponding to the second sliding grooves SGR2. Since the third sidewall portions SPW3 are disposed on the second sliding grooves SGR2, the pressing part PUL may be coupled to the moving case MVS.

The sliding grooves SGR, illustrated in FIG. 10, may be defined in mutually facing surfaces of the third sidewall portions SPW3. Hereinafter, for the convenience of description, any one third sidewall portion SPW3, among the third sidewall portions SPW3, will be described. The sliding groove SGR may be defined along the border of the third sidewall portion SPW3. The sliding groove SGR may include a first sliding groove SGR1, a second sliding groove SGR2, and a third sliding groove SGR3.

The first sliding groove SGR1 may be defined adjacent to an upper part of the third sidewall portion SPW3. The first sliding groove SGR1 may extend in a first direction DR1.

The second sliding groove SGR2 may be defined adjacent to a lower part of the third sidewall portion SPW3. The second sliding groove SGR2 may be defined under the first sliding groove SGR1. The second sliding groove SGR2 may extend in the first direction DR1. The first sliding groove SGR1 and the second sliding groove SGR2 may be symmetrical to each other in a third direction DR3.

The third sliding groove SGR3 may connect the first sliding groove SGR1 to the second sliding groove SGR2. The third sliding groove SGR3 may be defined in a curved shape.

Opposite sides of the module set PCR (refer to FIG. 2), which are opposed to each other in a second direction DR2, may be respectively disposed on the sliding grooves SGR. When the display device DD (refer to FIG. 1) switches from an extended mode to a reduced mode, or from the reduced mode to the extended mode, the module set PCR (refer to FIG. 2) may move along the sliding grooves SGR. This will be described in detail with reference to FIGS. 13B and 13E.

The roller part RU may include a roller ROL and roller protruding portions RPT. The roller ROL may extend in the second direction DR2. The roller ROL may have a cylindrical shape extending in the second direction DR2.

The roller protruding portions RPT may be respectively disposed on opposite sides of the roller ROL that are opposed to each other in the second direction DR2. The roller protruding portions RPT may extend from the opposite sides of the roller ROL in the second direction DR2.

The roller part RU may be coupled to the pressing part PUL. The roller part RU may be coupled to the stick portion PB of the pressing part PUL. The roller part RU may be coupled to the second portion PT2. The roller protruding portions RPT may be disposed in the roller openings ROP. Accordingly, the roller part RU may be connected to the pressing part PUL. The roller part RU may be connected to the moving case MVS through the pressing part PUL.

Referring to FIGS. 2, 8, 11, and 12, the driving parts DPT may be disposed adjacent to one side portion among opposite side portions of the pressing part PUL that are opposed to each other in the first direction DR1. The driving parts DPT may be connected to the pressing part PUL. The driving parts DPT may each be disposed on a corresponding driving groove MGR among the driving grooves MGR.

The driving parts DPT may each include a nut portion NTP, a stop portion STP, a screw portion SCW, and a motor portion MTR. The nut portions NTP may be coupled to a plate PLA. As illustrated in FIG. 12, the nut portions NTP may be coupled onto a lower surface of the plate PLA. The plate PLA may be a portion exposed to the outside regardless of an extended mode or a reduced mode of the display device DD (refer to FIG. 1). Accordingly, regardless of the extended mode or the reduced mode of the display device DD (refer to FIG. 1), positions in which the nut portions NTP are coupled to the plate PLA may be fixed.

The motor portions MTR may be connected to the pressing part PUL. The motor portions MTR may be respectively disposed on the driving grooves MGR defined in the stick portion PB. The motor portions MTR may be connected to the third sidewall portions SPW3 through the stick portion PB. The motor portions MTR may be connected to the moving case MVS through the third sidewall portions SPW3 disposed on the second sliding grooves SGR2.

Although not illustrated in the drawing, the motor portions MTR may rotate about a rotation axis parallel to the first direction DR1 through an external power.

The screw portion SCW may be connected to one side portion among opposite side portions of each of the motor portions MTR that are opposed to each other in the first direction DR1. When the motor portions MTR rotate about the rotation axis parallel to the first direction DR1, the screw portions SCW connected to the motor portions MTR may rotate about the rotation axis parallel to the first direction DR1. The first side portion, among the opposite side portions of each of the motor portions MTR opposed to each other in the first direction DR1, may be defined as a side opposed to a second side portion facing the stick portion PB.

The screw portions SCW may extend in the first direction DR1. The screw portions SCW may each have a stick shape. Grooves may be defined in outer surfaces of the screw portions SCW. The grooves may be defined in the outer surfaces of the screw portions SCW in a spiral shape.

The screw portions SCW may pass through the nut portions NTP. The screw portions SCW may extend in the first direction DR1 to be disposed in openings defined in the nut portions NTP, respectively. Although not illustrated in the drawing, bumps, corresponding to the grooves defined in the outer surfaces of the screw portions SCW, may be disposed inside the nut portions NTP. Accordingly, when the screw portions SCW rotate about the rotation axis parallel to the first direction DR1, the grooves, which are defined in the outer surfaces of the screw portions SCW, may engage with the bumps. Accordingly, when the screw portions SCW rotate about the rotation axis parallel to the first direction DR1, the screw portions SCW may move back and forth in the first direction DR1 with respect to the nut portions NTP.

The stop portions STP may be respectively disposed on first side portions of the screw portions SCW among opposite side portions that are opposed to each other in the first direction DR1. The first side portion, among the opposite side portions of each of the screw portions SCW opposed to each other in the first direction DR1, may be defined as a side opposed to a second side portion connected to each of the motor portions MTR.

The stop portions STP may each have a shape of a circular disc. The size of the radius of each of the stop portions STP may be larger than the size of the radius of each of the screw portions SCW. Accordingly, the stop portions STP may not pass through the nut portions NTP, and the stop portions STP may limit movement of the screw portions SCW in the first direction DR1.

Referring to FIGS. 2, 7, and 8, when the motor portions MTR, which have external power applied thereto, rotate about the rotation axis parallel to the first direction DR1, the screw portions SCW may rotate about the rotation axis parallel to the first direction DR1. When rotating, the screw portions SCW may move with respect to the nut portions NTP in the first direction DR1. When the screw portions SCW move in the first direction DR1, the motor portions MTR may move in the first direction DR1. When the motor portions MTR move in the first direction DR1, the pressing part PUL connected to the motor portions MTR may move in the first direction DR1. When the pressing part PUL moves in the first direction DR1, the moving case MVS and the roller part RU connected to the pressing part PUL may move in the first direction DR1.

The moving case MVS may move in the first direction DR1 with respect to the main case MCS. The second sidewall portions SPW2 may slide with respect to the first sidewall portions SPW1. The overlapping area of the first bottom portion BP1, of the main case MCS, and the second bottom portion BP2, of the moving case MVS, may be changed.

When the pressing part PUL moves in the first direction DR1, the supporting bars MSB (refer to FIG. 7), disposed on the sliding grooves SGR of the third sidewall portions SPW3, may move along the sliding grooves SGR. Some of the supporting bars MSB, disposed on the third sliding grooves SGR3, may be disposed on an outer surface of the roller ROL. The supporting bars MSB may move along the outer surface of the roller ROL.

When the supporting bars MSB (refer to FIG. 7) move along the sliding grooves SGR, the first extending portion LE1 (refer to FIG. 3) of an upper plate LTP disposed on the supporting bars MSB and the extending region DEP (refer to FIG. 3) of the display module DM may be exposed flat to the outside. Accordingly, the display device DD may operate from a reduced mode to an extended mode.

FIGS. 13A to 13F are drawings illustrating an extended mode or reduced mode of a display device.

FIGS. 13A, 13C, 13D, and 13F are exemplary plan views, FIG. 13B is a cross-sectional view taken along line II-II′ of FIG. 13A, and FIG. 13E is a cross-sectional view taken along line III-III′ of FIG. 13D.

FIGS. 13A, 13C, 13D, and 13F illustrate that nut portions NTP are substantially disposed on a lower surface of the plate PLA (refer to FIG. 12), but for the convenience of description, the plate PLA is omitted.

FIGS. 13A and 13B illustrate a display device DD in a reduced mode, and FIGS. 13D and 13E illustrate a display device DD in an extended mode.

FIGS. 13B and 13E are drawings illustrating supporting bars MSB disposed on a sliding groove SGR of a third sidewall portion SPW3.

For the convenience of description, the display module DM (refer to FIG. 3) and the upper plate LTP (refer to FIG. 3) are omitted.

For the convenience of description, FIGS. 13A, 13C, 13D, and 13F illustrate only a coupling supporting bar COB of a supporting plate MTP.

Since an extension module EMD and a coupling supporting bar COB in FIGS. 13A to 13F are the same as the extension module EMD in FIG. 8 and the coupling supporting bar COB in FIG. 7, the descriptions thereof will be omitted or simplified.

Referring to FIGS. 13A and 13B, when the display device DD is in a reduced mode, a moving case MVS may be accommodated in a main case MCS. When the display device DD is in the reduced mode, a supporting plate MTP may be accommodated in the moving case MVS. A coupling supporting bar COB may be accommodated in the moving case MVS.

The supporting plate MTP may be disposed on a sliding groove SGR defined in a third sidewall portion SPW3. In the reduced mode of the display device DD, the number of the supporting bars MSB disposed on a first sliding groove SGR1 may be smaller than the number of the supporting bars MSB disposed on a second sliding groove SGR2. The supporting bars MSB disposed on a third sliding groove SGR3 may be disposed on an outer surface of a roller ROL.

Elastic members EPT may be coupled to the moving case MVS and the coupling supporting bar COB. In particular, first fixation portions FPL1 of the elastic members EPT may be coupled to coupling protruding portions PTP of the moving case MVS, respectively.

Second fixation portions FPL2 of the elastic members EPT may be disposed under the coupling supporting bar COB. Second coupling openings POP2 defined in the second fixation portions FPL2 may overlap guide grooves GGR, respectively. Coupling units NSA may pass through the guide grooves GGR to be inserted in the second coupling openings POP2. Accordingly, the elastic members EPT may be connected to the supporting plate MTP.

Driving parts DPT may be disposed on the elastic members EPT. The driving parts DPT may be connected to a pressing part PUL.

Referring to FIGS. 13B and 13C, when an external power is applied to motor portions MTR, the motor portions MTR may rotate about a rotation axis parallel to a first direction DR1. When the motor portions MTR rotate, screw portions SCW connected to the motor portions MTR may rotate about the rotation axis parallel to the first direction DR1. In an embodiment, the motor portions MTR and the screw portions SCW may rotate clockwise, for example. When rotating, the screw portions SCW may move with respect to nut portions NTP in the first direction DR1. The motor potions MTR connected to the screw portions SCW may move in the first direction DR1.

When the motor portions MTR move in the first direction DR1, the pressing part PUL, connected to the motor portions MTR, may move in the first direction DR1. When the pressing part PUL moves in the first direction DR1, the moving case MVS, connected to the pressing part PUL, may move in the first direction DR1. The moving case MVS may move in the first direction DR1 with respect to the main case MCS. Since the moving case MVS moves in the first direction DR1, the overlapping area of the main case MCS and the moving case MVS may be reduced.

When the pressing part PUL moves in the first direction DR1, the roller ROL, connected to the pressing part PUL, may move in the first direction DR1. The roller ROL moving in the first direction DR1 may push the supporting bars MSB in the first direction DR1. By the roller ROL, the supporting bars MSB disposed on the third sliding groove SGR3 may move toward the second sliding groove SGR2 along the outer surface of the roller ROL. The supporting bars MSB disposed on the second sliding groove SGR2 may move toward the first sliding groove SGR1 along the sliding groove SGR. The coupling supporting bar COB, among the supporting bars MSB, may move in the first direction DR1. As the supporting bars MSB move, the display module DM (refer to FIG. 3) and the upper plate LTP (refer to FIG. 3), disposed on the supporting bars MSB, may also move to an upper part.

The moving speed of the coupling supporting bar COB may be different from the moving speed of the moving case MVS. The moving speed of the coupling supporting bar COB may be higher than the moving speed of the moving case MVS. Due to the difference in moving speed between the coupling supporting bar COB and the moving case MVS, the distance between the coupling protruding portions PTP and the coupling supporting bar COB may gradually increase. As the distance between the coupling protruding portions PTP and the coupling supporting bar COB increases, the elastic members EPT, connected to the coupling supporting bar COB and the coupling protruding portions PTP, may rotate about a rotation axis parallel to a third direction DR3. When the elastic members EPT rotate, the coupling units NSA, passing through the second fixation portions FPL2 and the guide grooves GGR, may slide in the guide grooves GGR in the second direction DR2. Accordingly, the distance between the second fixation portions FPL2 may increase.

The coupling units NSA may reach end portions of the guide grooves GGR before stop portions STP limit movement of the screw portions SCW. The distance between the coupling units NSA connected to the coupling supporting bar COB may become maximum. At this time, the second fixation portions FPL2, connected to the coupling units NSA, may rotate, and thus the distance between the second fixation portions FPL2 may become maximum. When the elastic members EPT rotate, a first length L1, which is defined as an initial length of each of the elastic members EPT, may be uniform.

Referring to FIGS. 13D and 13E, the motor portions MTR may keep rotating about a rotation axis parallel to a first direction DR1 until the stop portions STP limit movement of the screw portions SCW in the first direction DR1. The pressing part PUL, the roller ROL, and the moving case MCS may keep moving in the first direction DR1 by the motor portions MTR. The coupling supporting bar COB may move in the first direction DR1 by the roller ROL.

When the coupling supporting bar COB moves in the first direction DR1, the distance between the coupling supporting bar COB and the coupling protruding portions PTP may increase. Accordingly, the length of each of the elastic members EPT, connected to the coupling supporting bar COB, may increase. The length of an elastic body SPR of each of the elastic members EPT may increase. As the length of the elastic body SPR increases, elastic force that the elastic body SPR tends to return to a state in first length LI may be generated. The elastic members EPT may apply the elastic force to the coupling supporting bar COB.

When the movement of the screw portions SCW in the first direction DR1 is limited by the stop portions STP, the pressing part PUL, the roller ROL, and the moving case MVS may stop. When the moving case MVS stops, the overlapping area of the main case MCS and the moving case MVS may become minimum. When the overlapping area of the moving case MVS and the main case MCS is at its minimum, the display device DD (refer to FIG. 1B) may be in the extended mode.

In the extended mode of the display device DD (refer to FIG. 1B), the number of the supporting bars MSB disposed on the first sliding groove SGR1 may be larger than the number of the supporting bars MSB disposed on the second sliding groove SGR2. The extending region DEP (refer to FIG. 3), which is disposed on the supporting bars MSB, may also have an increased area to be exposed to the outside.

When the display device DD (refer to FIG. 1B) is in the extended mode, the length of the elastic body SPR of the elastic member EPT may be defined as a second length L2. The second length L2 may be larger than the first length L1 (refer to FIG. 13C). Accordingly, elastic force may be generated in the elastic body SPR.

Referring to FIGS. 13D, 13E, and 13F, when the display device DD (refer to FIG. 1B) switches from the extended mode to the reduced mode, the motor portions MTR may rotate about a rotation axis parallel to a first direction DR1. When the motor portions MTR rotate, the screw portions SCW connected to the motor portions MTR may rotate about the rotation axis parallel to the first direction DR1. In an embodiment, the motor portions MTR and the screw portions SCW may rotate counterclockwise, for example. As rotating, the screw portions SCW may move in the first direction DR1 with respect to the nut portions NTP. When the screw portions SCW move in the first direction DR1, the motor portions MTR, connected to the screw portions SCW, may move in the first direction DR1. When the motor portions MTR move in the first direction DR1, the pressing part PUL, connected to the motor portions MTR, may move in the first direction DR1.

When the pressing part PUL moves in the first direction DR1, the moving case MVS connected to the pressing part PUL may move in the first direction DR1. When the display device DD switches from the extended mode to the reduced mode, the overlapping area of the main case MCS and the moving case MVS may increase.

As the pressing part PUL moves in the first direction DR1, the supporting bars MSB disposed on the sliding groove SGR may be moved. At this time, static friction force may be generated between the supporting bars MSB and the third sidewall portions SPW3 in contact with the supporting bars MSB. The elastic members EPT, connected to the coupling supporting bar COB, may apply elastic force to the coupling supporting bar COB. The elastic members EPT may apply the elastic force, which is greater than the static friction force, to the supporting plate MTP. The elastic body SPR, which has applied the elastic force to the supporting plate MTP, may shrink from the second length L2 to the first length L1.

The supporting bars MSB, to which the elastic force greater than the static friction force is applied, may move from the first sliding groove SGR1 to the second sliding groove SGR2 via the third sliding groove SGR3. Accordingly, the display module DM (refer to FIG. 3), disposed on the supporting bars MSB, may move into the moving case MVS.

Hereinafter, a process in which the display device DD (refer to FIG. 1B) switches from the extended mode to the reduced mode proceeds in reverse order of the process described with reference to FIGS. 13A to 13E, and thus the description thereof will be omitted.

FIGS. 14A and 14B are drawings illustrating supporting bars according to Comparative Example. FIGS. 14C and 14D are drawings illustrating an embodiment of supporting bars according to the inventive concept.

FIGS. 14A and 14B are cross-sectional views illustrating supporting bars MSB and MSB′ and a third sidewall portion SPW3 when viewed from a second direction DR2.

Referring to FIGS. 14A and 14B, when the display device DD (refer to FIG. 1B) switches from an extended mode to a reduced mode, the supporting bars MSB′ may move along a sliding groove SGR. At this time, static friction force may be generated between the supporting bars MSB′ and the sliding groove SGR. Due to the static friction force, the moving speeds between adjacent supporting bars MSB′ may differ from each other. Accordingly, as illustrated in FIGS. 14B, the distance between the adjacent supporting bars MSB′ is reduced, and thus the supporting plate MTP (refer to FIG. 7) may be deformed. Therefore, a display module DM′ disposed on the supporting plate MTP (refer to FIG. 7) may also be deformed. In an embodiment, an upper plate LTP′ may be interposed between the supporting plate MTP and the display module DM′.

Referring to FIGS. 13D, 13F, 14C, and 14D, when the display device DD (refer to FIG. 1B) switches from the extended mode to the reduced mode, the elastic bodies SPR of the elastic members EPT may be stretched from the first length L1 to the second length L2. As the lengths of the elastic bodies SPR increase, the elastic bodies SPR may generate elastic force. The elastic bodies SPR, connected to the coupling supporting bar COB, may apply the elastic force to the coupling supporting bar COB. The magnitude of the elastic force may be greater than that of the static friction force. Accordingly, the supporting bars MSB adjacent to each other may move at the same speed, and the distance between the adjacent supporting bars MSB may remain constant. Therefore, the supporting plate MTP (refer to FIG. 7) may be prevented from being deformed, thereby preventing deformation of the display module DM disposed on the supporting plate MTP.

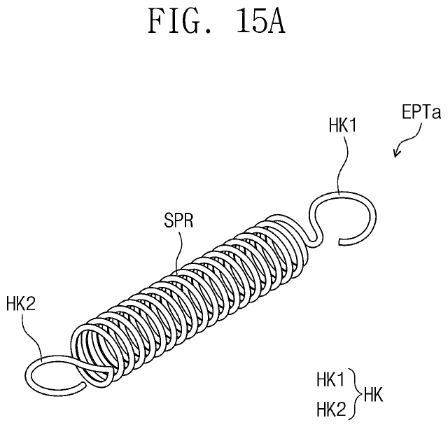

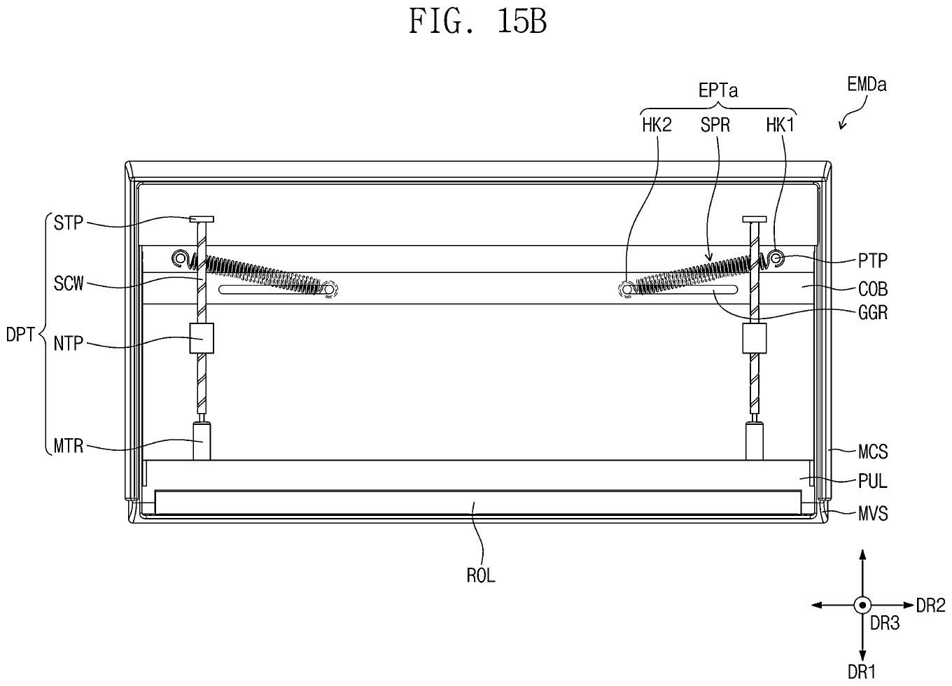

FIGS. 15A and 15B are drawings illustrating another embodiment of an elastic member according to the inventive concept.

FIG. 15A is a perspective view illustrating an elastic member EPTa, and FIG. 15B is a plan view illustrating an extension module EMDa.

FIG. 15B illustrates the extension module EMDa in a reduced mode.

FIG. 15B illustrates only a coupling supporting bar COB among the supporting bars MSB (refer to FIG. 7).

In an embodiment, a main case MCS, a moving case MVS, a roller ROL, a pressing part PUL, a driving part DPT, a coupling supporting bar COB, and coupling units NSA in FIG. 15B are respectively the same as the main case MCS, the moving case MVS, the roller ROL, the pressing part PUL, the driving part DPT, the coupling supporting bar COB, and the coupling units NSA in FIG. 13A, and thus, the descriptions thereof will be omitted or simplified, for example.

Referring to FIG. 15A, the elastic member EPTa may include an elastic body SPR and rings HK respectively disposed on opposite side portions of the elastic body SPR. The elastic body SPR may be a tension spring. The rings HK may extend from the opposite side portions of the elastic body SPR. Substantially, the elastic body SPR and the rings HK may be unitary.

The rings HK may include a first ring HK1 and a second ring HK2. The first ring HK1 and the second ring HK2 may be symmetrical with respect to the elastic body SPR.

Referring to FIGS. 15A and 15B, hereinafter, for the convenience of description, any one elastic member EPTa among a plurality of elastic members EPTa will be described. The first ring HK1, among the rings HK of the elastic member EPTa, may be coupled to each of coupling protruding portions PTP of the moving case MVS. Through the first ring HK1, the elastic member EPTa may be connected to the moving case MVS. The second ring HK2 may be connected to the coupling supporting bar COB through the coupling unit NSA.

Although not illustrated in the drawing, when the moving case MVS moves in a first direction DR1 with respect to the main case MCS, the elastic member EPTa may rotate about a rotation axis parallel to a third direction DR3. When the elastic member EPTa rotates, the second ring HK2 may move along a guide groove GGR in a second direction DR2. The distance between the second rings HK2, spaced apart from each other in the second direction DR2, may increase.

Although not illustrated in the drawing, after the coupling units NSA are respectively disposed on end portions of the guide grooves GGR, the coupling supporting bar COB may keep moving in the first direction DR1. Accordingly, the elastic member EPTa may be stretched. The elastic body SPR of the elastic member EPTa may be stretched. As the elastic body SPR is stretched, elastic force may be generated.

Referring to FIGS. 13E and 15B, when the display device DD (refer to FIG. 1A) switches from the extended mode to the reduced mode, the elastic members EPTa may apply elastic force to the coupling supporting bar COB. The magnitude of the elastic force may be greater than that of friction force generated between the supporting bars MSB and the third sidewall portion SPW3. Accordingly, the moving speed of the supporting bars MSB may be the same, and the distance between adjacent supporting bars MSB may remain constant. Therefore, the supporting plate MTP may be prevented from being deformed, thereby preventing deformation of the display module DM (refer to FIG. 3) disposed on the supporting plate MTP.

In an embodiment of the inventive concept, an elastic member may be coupled to a moving case and a supporting plate including supporting bars. When a display device switches from an extended mode, in which an exposed surface of a display module extends, to a reduced mode, in which the exposed surface of the display module shrinks, static friction force may be generated between the supporting bars and a pressing part. The elastic member may apply elastic force, greater than the static friction force, to the supporting plate. Accordingly, the supporting bars may be easily moveable without deformation. Therefore, it may be possible to prevent deformation of the supporting bars.

Although the embodiments of the inventive concept have been described, it is understood that the inventive concept should not be limited to these embodiments but various changes and modifications may be made by one ordinary skilled in the art within the spirit and scope of the inventive concept as hereinafter claimed. In addition, the embodiments of the inventive concept disclosed herein are not intended to limit the technological idea of the inventive concept, but it should be construed all technological ideas within the scope of the following claims and equivalents thereof are included in the scope of rights of the inventive concept.

What is claimed is:

1. A display device comprising:
a display module;
a supporting plate disposed under the display module, the supporting plate including:
a plate; and
a plurality of supporting bars arranged in a first direction along with the plate, and extending in a second direction crossing the first direction;
a main case disposed under the supporting plate;
a moving case which is disposed between the supporting plate and the main case, and moves in the first direction with respect to the main case; and
an elastic member disposed on an upper surface of the moving case, and coupled to the supporting plate,
wherein in a state in which an overlapping area of the moving case and the main case is at a minimum, the elastic member is stretched and applies elastic force to the supporting plate.

2. The display device of claim 1, wherein the elastic member is provided in plural,
first side portions of a plurality of elastic members are coupled onto the upper surface of the moving case, and second side portions of the plurality of elastic members, opposed to the first side portions, are rotatably coupled to the supporting plate.

3. The display device of claim 2, wherein a supporting bar spaced farthest apart from the plate, among the plurality of supporting bars, is defined as a coupling supporting bar,
a plurality of guide grooves extending in the second direction is defined in an upper surface of the coupling supporting bar, and second side portions of the plurality of elastic members are rotatably coupled to the plurality of guide grooves.

4. The display device of claim 3, wherein in a state in which the overlapping area of the moving case and the main case increases, the display module operates in a reduced mode in which the display module shrinks into the moving case,
in a state in which the overlapping area of the moving case and the main case decreases, the display module operates in an extended mode in which the display module extends out of the moving case, and
in a state in which the reduced mode is switched to the extended mode, a distance between second side portions of the plurality of elastic members increases.

5. The display device of claim 4, wherein in a state in which the distance between second side portions of the plurality of elastic members is at its maximum, each of the plurality of elastic members is stretched.

6. The display device of claim 1, further comprising a pressing part disposed on the moving case, and including a plurality of sidewall portions facing each other in the second direction,
wherein a plurality of sliding grooves is defined in mutually facing surfaces of the plurality of sidewall portions, and opposite sides of each of the plurality of supporting bars, opposed to each other in the second direction, are disposed on the plurality of sliding grooves.

7. The display device of claim 6, further comprising:
a roller, in a plan view, extending in the second direction and disposed between the plurality of sidewall portions facing each other; and
a driving part disposed between the supporting plate and the elastic member, and connected to the pressing part.

8. The display device of claim 7, wherein supporting bars, among the plurality of supporting bars, are disposed on an outer surface of the roller.

9. The display device of claim 7, wherein the driving part comprises:
a nut portion disposed on a lower surface of the plate;
a screw portion which extends in the first direction and passes through the nut portion; and
a motor portion connected to the pressing part, and
in a state in which the motor portion rotates about a rotation axis parallel to the first direction, the moving case moves in the first direction with respect to the main case.

10. The display device of claim 1, wherein the elastic member includes a tension spring.

11. The display device of claim 10, wherein the elastic member comprises:
a first fixation portion coupled to the moving case; and
a second fixation portion coupled to the supporting plate, and
the tension spring is disposed between the first fixation portion and the second fixation portion.

12. A display device comprising:
a display module;
a supporting plate which is disposed under the display module, and in which a plurality of guide grooves is defined;
a main case disposed under the supporting plate;
a moving case disposed between the main case and the supporting plate, and slidably coupled to the main case; and
a plurality of elastic members disposed on an upper surface of the moving case, and coupled to the plurality of guide grooves,
wherein in a state in which the moving case moves in a first direction with respect to the main case, portions of the plurality of elastic members, which are coupled to the plurality of guide grooves, become close to each other or away from each other, and
in a state in which a distance between the portions of the plurality of elastic members is at a maximum, the plurality of elastic members is stretched and applies elastic force to the supporting plate.

13. The display device of claim 12, wherein the supporting plate comprises:
a plate including a flat surface defined by the first direction and a second direction crossing the first direction; and
a plurality of supporting bars arranged in the first direction along with the plate, and extending in the second direction, and
the plurality of guide grooves is defined in a coupling supporting bar which is defined as a supporting bar, among the plurality of supporting bars, spaced farthest apart from the plate.

14. The display device of claim 13, further comprising a pressing part coupled to the moving case, and including a plurality of sidewall portions facing each other in the second direction,
wherein a plurality of sliding grooves is defined in mutually facing surfaces of the plurality of sidewall portions, and opposite sides of each of the plurality of supporting bars, opposed to each other in the second direction, are disposed on the plurality of sliding grooves.

15. The display device of claim 14, further comprising:
a roller disposed between the plurality of sidewall portions; and
a driving part disposed between the moving case and the supporting plate, and connected to the pressing part,
wherein supporting bars, among the plurality of supporting bars, are disposed on an outer surface of the roller.

16. The display device of claim 12, further comprising a plurality of coupling units disposed on the plurality of guide grooves to connect the supporting plate and the plurality of elastic members to each other,
wherein first side portions of the plurality of elastic members are coupled onto the upper surface of the moving case, and second side portions of the plurality of elastic members, disposed to be opposed to the first side portions, are rotatably coupled to the plurality of guide grooves by the plurality of coupling units.

17. The display device of claim 16, wherein in a state in which second side portions of the plurality of elastic members rotate, the plurality of coupling units moves along the plurality of guide grooves in a second direction crossing the first direction.

18. The display device of claim 16, wherein in a state in which an overlapping area of the moving case and the main case increases, the display module operates in a reduced mode in which the display module shrinks into the main case,
in a state in which the overlapping area of the moving case and the main case decreases, the display module operates in an extended mode in which the display module extends out of the main case, and
a distance between second side portions of the plurality of elastic members in the reduced mode is smaller than a distance between second side portions of the plurality of elastic members in the extended mode.

19. The display device of claim 12, wherein an elastic member of the plurality of elastic members further comprises a tension spring.

20. The display device of claim 19, wherein the elastic member further comprises:
a first fixation portion coupled onto an upper surface of the moving case; and
a second fixation portion coupled to each of the plurality of guide grooves, and
the tension spring is disposed between the first fixation portion and the second fixation portion.
